(19) United States
(12) Patent Application Publication
(10) Pub. No.: US 2010/0232179 A1
(43) Pub. Date: Sep. 16, 2010

(54) PRINTED CIRCUIT BOARD AND BACK LIGHT MODULE USING THE SAME

(75) Inventors: JIAN-SHIHN TSANG, Tu-Cheng (TW); LUNG-HSIN CHEN, Tu-Cheng (TW); CHIH-YUNG LIN, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: ADVANCED OPTOELECTRONIC TECHNOLOGY, INC., Hsinchu Hsien (TW)

(21) Appl. No.: 12/713,178

(22) Filed: Feb. 26, 2010

(30) Foreign Application Priority Data
Mar. 13, 2009 (TW) 98203881

(51) Int. Cl. F21V 7/04; H05K 1/00; H05K 1/16; F21V 19/00

(52) U.S. Cl. 362/613; 174/250; 174/260; 362/382

(57) ABSTRACT

A back light module includes a printed circuit board and a plurality of surface mounting elements mounted on the printed circuit board. Each surface mounting element is an LED lighting element. The printed circuit board has a plurality of pads. Each of the pads includes a first bar and two second bars extending respectively from two ends of the first bar. The surface mounting element includes a plurality of pins. The pins are placed on two sides of the surface mounting element. The pins are soldered on the pads.

### BACKGROUND

1. Technical Field

The present disclosure relates generally to a printed circuit board and a module with a surface mounting element using the printed circuit board, and more particularly to a back light module using the printed circuit board.

2. Description of Related Art

In recent years, light emitting diodes (LEDs) have been developed capable of emitting red, green, and blue light. Therefore, the LEDs have been increasingly used for various applications such as light sources of back light modules in displays or monitors.

A typical back light module includes a printed circuit board (PCB), an LED package mounted on the PCB, and a light guide plate located adjacent to the LED package. The light generated by the LED package can project into the light guide plate. Usually, the LED package includes two pins, and the PCB forms two corresponding pads thereon. The pins are soldered onto the pads by a surface mounting technology (SMT), to perform an electronic connection between the LED package and the PCB. However, different LED packages have different pins which are located at different positions. Therefore, when confronting different LED packages, multiple types of PCBs having different pads matching with the different pins of the LED packages are needed, which resulting in an increase of storage cost or even a risk of overstock.

What is needed therefore is a PCB and a back light module applying the PCB which has a good compatibility with different LED packages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a back light module in accordance with an embodiment of the present disclosure.

FIG. 2 is an isometric view of a light source of the back light module in FIG. 1.

FIG. 3 is a cross-sectional view of the light source in FIG. 2.

FIG. 4 is an isometric view of a part of a printed circuit board of the back light module in FIG. 1.

FIG. 5 is an isometric view of a light source of a back light module in accordance with a second embodiment of the present disclosure.

FIG. 6 is a cross-sectional view of the light source in FIG. 5.

FIG. 7 is an isometric view of a part of a printed circuit board in accordance with a second embodiment of the present disclosure.

FIG. 8 is an isometric view of a part of a printed circuit board in accordance with a third embodiment of the present disclosure.

### DETAILED DESCRIPTION

The module with a surface mounting element of the present disclosure is applied to a back light module as an example.

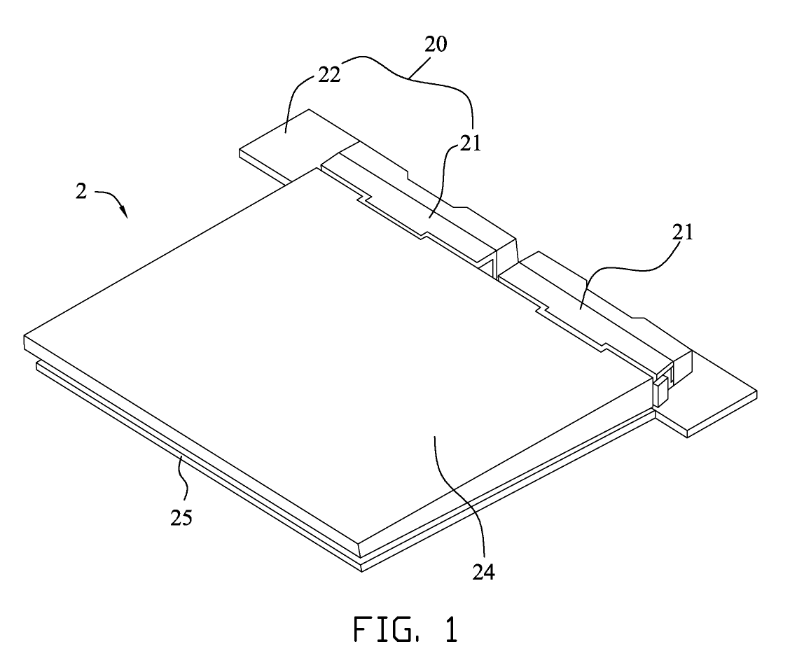

As shown in FIG. 1, a back light module 2 comprises a light guiding plate 24, a light source module 20 and a reflecting sheet 25. The back light module 2 can be applied to such as a PDA or a notebook. The light source module 20 comprises a printed circuit board (PCB) 22 and a plurality of light sources 21 mounted on the PCB 22 by a surface mounting technology (SMT). The light sources 21 are located at a lateral side of the light guiding plate 24, to allow light generated by the light sources 21 to project into the light guiding plate 24. The reflecting sheet 25 is located at a bottom of the light guiding plate 24. In the present embodiment, the light guiding plate 24 is configured to be a flat translucent plate, and is capable of reflecting the light toward a light exiting surface thereof by inner walls of the light guiding plate 24. The light guiding plate 24 is preferred to be made of material with good light transmittance and molding properties such as acrylic resin, polycarbonate, amorphous polyolefin resin, polystyrene resin or glass.

In addition, a diffusion sheet (not shown) is adhered on the light guiding plate 24. The diffusion sheet can modulate the property of the light guiding plate 24. Different diffusion sheets are applied according to different light guiding plates 24. For example, a diffusion sheet with a thickness of about 100 μm can be applied to a polycarbonate light guiding plate 24 with a thickness of 20 mm, to increase optical uniformity of the light sources 21. The diffusion sheet can be directly located on the light guiding plate 24, or be adhered on the light guiding plate 24 via adhesive. The space between the diffusion sheet and the light guiding plate 24 is preferably 0-10 mm. The diffusion sheet is preferably made of, but not limited to, polyethylene terephthalate, as long as having a resistance to deformation or damage when confronting the heat generated by the light sources 21.

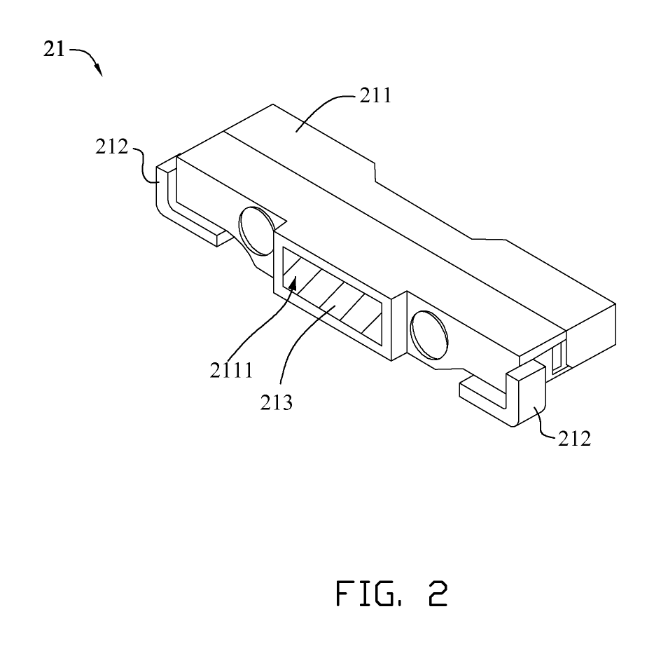

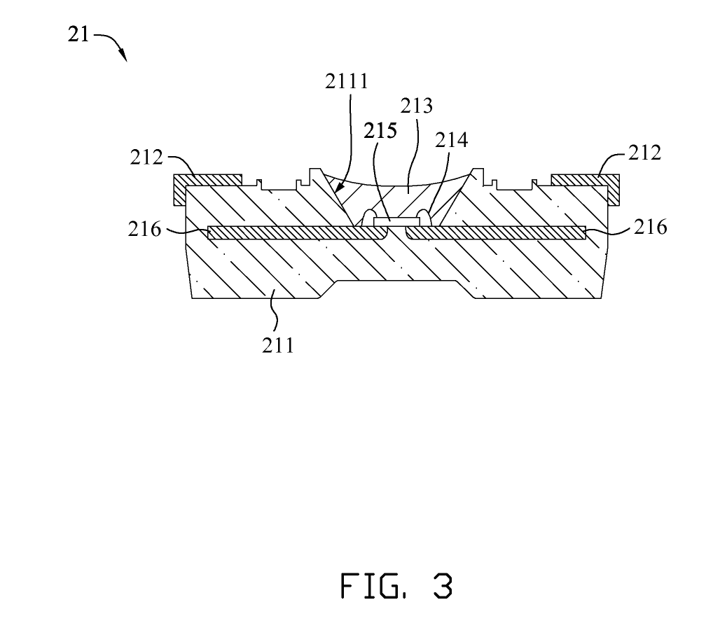

FIGS. 2 and 3 represent a light source 21 of the light source module 20 of the back light module 2. The light source 21 comprises a substrate 211 and two pins 212 formed thereon. The substrate 211 is made of thermoplastic resin such as poly resin acid amide ammonia or polybutylene terephthalate. A rectangular groove 2111 is defined in the substrate 211 for receiving a light emitting element 215 therein. In the present embodiment, the light emitting element 215 is a light emitting diode (LED) chip. Understandably, the light emitting element 215 can be others such as a candescent bulb in alternative embodiments.

The light source 21 further comprises two electrodes 216, two wires 214 each connecting to the light emitting element 215 and a corresponding electrode 216, and a transparent encapsulant 213 secured in the groove 2111 and covering the light emitting element 215 and the wires 214. Each electrode 216 has a part embedded in the substrate 211, and another part exposed out of the substrate 211 to form the pin 212. The two pins 212 are located at two lateral sides of a front end of the substrate 211 respectively. Each pin 212 has a substantially L shape with an upper portion thereof adhered to the lateral side of the substrate 211 and a lower portion thereof adhered to a bottom of the substrate 211.

The resistance of the electrodes 216 is less than 300 μΩ-cm, and preferably less than 3 μΩ-cm, and the electrodes 216 can be made of copper, iron, or gold-plated/silver-plated aluminum.

The encapsulant 213 serves to support and protect the electrodes 216 and the light emitting element 215. The encapsulant 213 can be made of transparent organic or inorganic material such as silicone, epoxide resin, urea resin, or glass. In addition, other material such as thickening agents, light sensitive agents, barium titanium compounds, titanium oxides, aluminum oxides, silicon oxides, silicon dioxides, calcium bicarbonates, calcium carbonates can be added into the encapsulant 213. Further, a light emitting surface of the encapsulant 213 can be configured to be concave or convex mirrors to obtain a lens property.

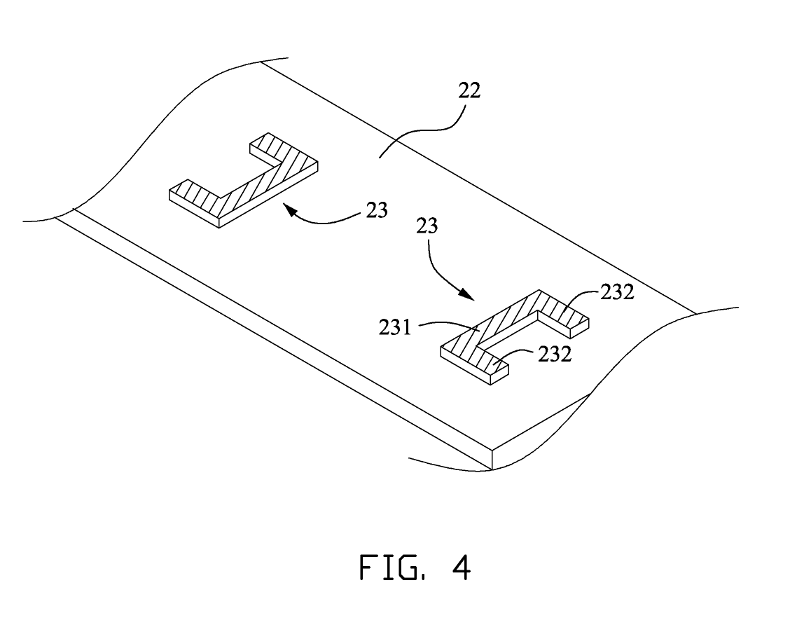

The PCB 22 forms a plurality of soldering pads 23 thereon, and every two soldering pads 23 form a pad unit to match with the two pins 212 of a corresponding light source 21. Referring to FIG. 4, only one pad unit of the PCB 22 is shown. Each soldering pad 23 comprises a first bar 231 and two second bars 232 extending perpendicularly from two opposite ends of the first bar 231. The extending direction of the two second bars 232 of one soldering pad 23 in a pad unit is opposite to that of the two second bars 232 of the other soldering pad 23 in the pad unit. That is, the two second bars 232 of one soldering pad 23 extend away from the first bar 231 of the other soldering pad 23 in the pad unit.

The PCB 22 is made of non-conductive material and the soldering pads 23 are made of conductive material such as copper. Referring to FIGS. 2 and 4, when the light source 21 is soldered onto the PCB 22, a solder paste can be adhered to a front half portion of the soldering pads 23 to bond with the pins 212 of the light source 21 and the soldering pads 23 of the PCB 22.

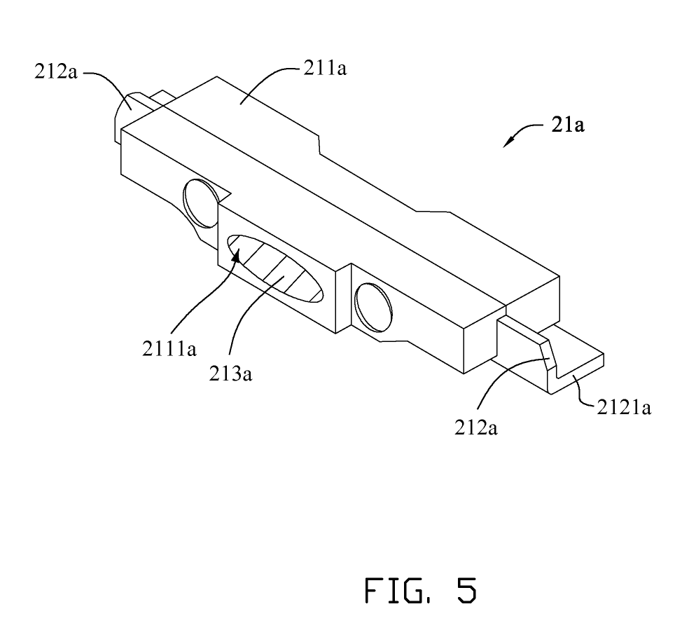

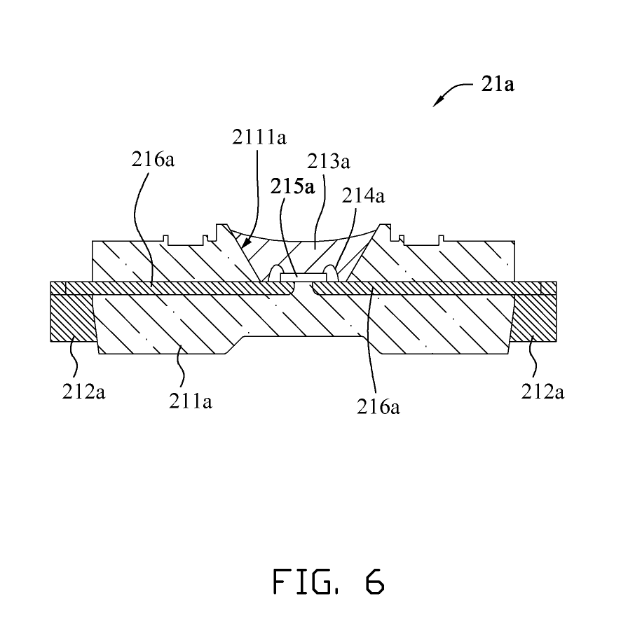

FIGS. 5 and 6 show a light source 21a of a module in accordance with a second embodiment of present disclosure. The light source 21a comprises a substrate 211a and two pins 212a formed on the substrate 211a. The substrate 211a is made of thermoplastic resin. A groove 2111a is defined in the substrate 211a for receiving a light emitting element 215a therein. In this embodiment, the light emitting element 215a is an LED. The light source 21a further comprises two electrodes 216a and two wires 214a each connecting to the light emitting element 215a and a corresponding electrode 216a. Each electrode 216a has a part embedded in the substrate 211a and another part exposed out of the substrate 211a to form a corresponding pin 212a. The two pins 212a are located at two lateral sides of a rear end of the substrate 211a respectively. Each pin 212a has a substantially L shape with an upper portion thereof extending outwards from the lateral side of the substrate 211 a and a lower portion thereof extending rearwards from a bottom of the upper portion. An encapsulant 213a is received in the groove 2111 a to cover and protect the light emitting element 215a and the wires 214a.

Compared with the rectangular groove 2111 of the light source 21 in the first embodiment, the groove 2111a of the substrate 211a of the light source 21a in the second embodiment has an elliptic shape, for increasing a strength of sidewalls of the substrate 211a defining the groove 2111a.

Another difference between the light sources 21, 21a of the first and second embodiments is that, the pins 212 of the light source 21 of the first embodiment are located at two lateral sides of the front end of the substrate 211; however, the pins 212a of the light source 21a are located at two lateral sides of the rear end of the substrate 211a. When the light source 21a is to be soldered onto the PCB 22, a solder paste can be adhered to a rear half portion of the soldering pads 23 to bond with the pins 212a of the light source 21a and the soldering pads 23 of the PCB 22.

As described above, it is understood that the PCB 22 is capable of being used with different light sources 21(21a) without modification. That is, when confronting different light sources 21(21a), there is no need to prepare multiple types of PCBs, which reduces a storage cost.

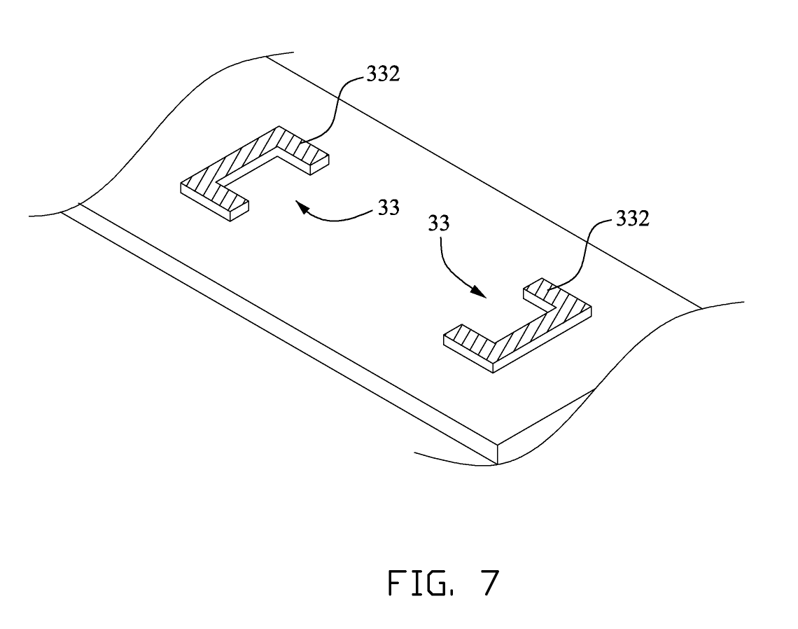

It is noted that the extending direction of the second bars can be changed in alternative embodiments. Referring to FIG. 7, a pad unit which consists of two soldering pads 33 of a PCB in accordance with a second embodiment of the disclosure is presented. The second bar 332 of one soldering pad 33 extends toward the first bar, specifically the corresponding second bar 332 of the other soldering pad 33 of the pad unit.

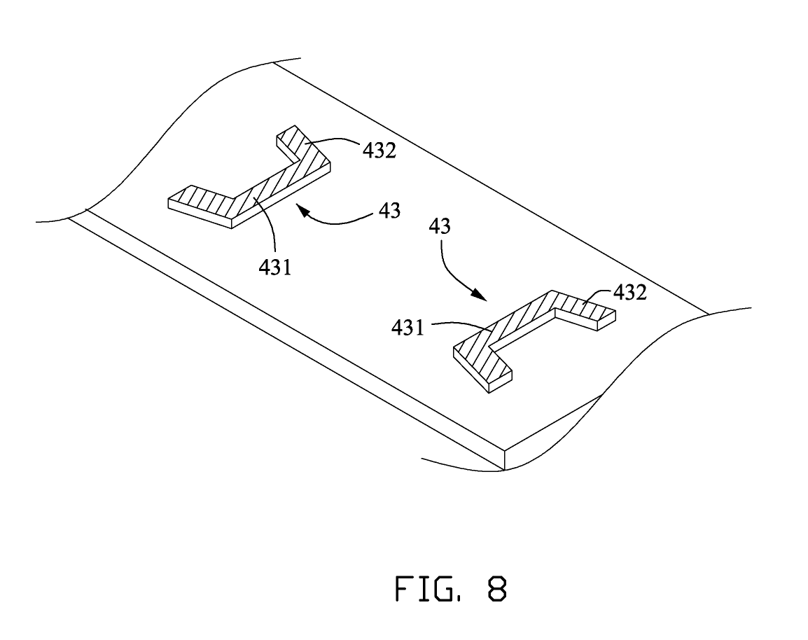

Furthermore, the second bar is not limited to perpendicular to the first bar. FIG. 8 shows a PCB in accordance with a third embodiment of the disclosure. The second bars 432 of each soldering pad 43 of the PCB extend slantwise from two opposite ends of the first bar 431 of the soldering pad 43.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A printed circuit board (PCB) comprising a plurality of soldering pads formed thereon, wherein the soldering pads are configured for electrically connecting with electrodes of surface mounting elements, and wherein each soldering pad comprises a first bar and two second bars respectively extending from two opposite ends of the first bar.

2. The PCB of claim 1, wherein each two soldering pads form a pad unit, and an extending direction of the two second bars of one soldering pad in the pad unit is opposite to that of the two second bars of the other soldering pad in the pad unit.

3. A module comprising:
a PCB with a plurality of soldering pads formed thereon, each soldering pad comprising a first bar and two second bars extending from two ends of the first bar; and
at least one surface mounting element each comprising a plurality of pins located at two lateral sides of the surface mounting element for connecting to the soldering pads of the PCB.

4. The module of claim 3, wherein each two soldering pads form a pad unit, and the two second bars of one soldering pad in the pad unit extend toward the first bar of the other soldering pad in the pad unit.

5. The module of claim 3, wherein each two soldering pads form a pad unit, and the two second bars of one soldering pad in the pad unit extend away from the first bar of the other soldering pad in the pad unit.

6. The module of claim 3, wherein the surface mounting element is a light source.

7. The module of claim 6, wherein the surface mounting element is an LED light source.

8. The module of claim 6, wherein the light source comprises a substrate with a groove defined therein, a light emitting element received in the groove, and an transparent encapsulant received in the groove and covering the light emitting element.

9. The module of claim 8, wherein the groove has an elliptic shape.

10. The module of claim 3, wherein the pins are located at a front end of the surface mounting element, and the pins each have an L shape with an upper portion thereof adhered to the lateral side of the substrate and a lower portion thereof adhered to a bottom of the substrate.

11. The module of claim 3, wherein the pins are located at a rear end of the surface mounting element, and the pins each have an L shape with an upper portion thereof extending outwards from the lateral side of the substrate and a lower portion thereof extending rearwards from a bottom of the upper portion.

12. A back light module comprising:
a PCB with a plurality of soldering pads formed thereon, each soldering pad comprising a first bar and two second bars extending from two ends of the first bar;
a plurality of light sources mounted on the PCB by a surface mounting technology, each light source comprising two pins located at two lateral sides of the surface mounting element connecting to corresponding two of the soldering pads of the PCB; and
a light guiding plate located adjacent to the light sources to allow light generated by the light sources to project into the light guiding plate.

13. The back light module of claim 12, wherein each two soldering pads form a pad unit to connect to a corresponding light source, and the two second bars of one soldering pad in the pad unit extend toward the first bar of the other soldering pad in the pad unit.

14. The back light module of claim 12, wherein each two soldering pads form a pad unit to connect to a corresponding light source, and the two second bars of one soldering pad in the pad unit extend away from the first bar of the other soldering pad in the pad unit.

15. The back light module of claim 12, wherein the two second bars extending perpendicularly from two opposite ends of the first bar.

16. The back light module of claim 12, wherein the two second bars extending slantwise from two opposite ends of the first bar.
